(19) United States
(12) Patent Application Publication
(10) Pub. No.: US 2025/0294743 A1
(43) Pub. Date: Sep. 18, 2025

(54) MEMORY DEVICE AND METHOD OF MANUFACTURING THE MEMORY DEVICE

(71) Applicant: SK hynix Inc., Icheon-si Gyeonggi-do (KR)

(72) Inventor: Dae Sung EOM, Icheon-si Gyeonggi-do (KR)

(73) Assignee: SK hynix Inc., Icheon-si Gyeonggi-do (KR)

(21) Appl. No.: 18/776,907

(22) Filed: Jul. 18, 2024

(30) Foreign Application Priority Data
Mar. 14, 2024 (KR) 10-2024-0035747

(51) Int. Cl. H10B 43/27

(52) U.S. Cl. CPC H10B 43/27

(57) ABSTRACT

Provided herein is a memory device and a method of manufacturing the memory device. The method of manufacturing a memory device includes forming a stacked body including first and second material layers on a lower structure, forming first openings passing through the stacked body, filling the first openings with preliminary contact plugs, respectively, forming, on the stacked body, a stepped structure including steps respectively corresponding to the preliminary contact plugs, forming second openings passing through respective steps of the stepped structure and open at least portions of the first openings, respectively, at different depths, exposing side surfaces of the second material layers by removing respective portions of the preliminary contact plugs adjacent to respective first sides of the first openings through the second openings, and forming the stacked body having a reverse step structure by removing exposed portions of the second material layers.

### CROSS-REFERENCE TO RELATED APPLICATION

The present application claims priority under 35 U.S.C. § 119(a) to Korean patent application number 10-2024-0035747 filed on Mar. 14, 2024, in the Korean Intellectual Property Office, the entire contents of which application is incorporated herein by reference.

### BACKGROUND

### 1. Technical Field

Various embodiments of the present disclosure generally relate to a memory device and a method of manufacturing the memory device, and more particularly to a memory device including a memory block having a three-dimensional (3D) structure and a method of manufacturing the memory device.

### 2. Related Art

Memory devices may include nonvolatile memory devices in which stored data is retained even when power supply is interrupted. The nonvolatile memory devices may be classified into a two-dimensional (2D) structure and a three-dimensional (3D) structure according to the structure in which memory cells are arranged. The memory cells of a nonvolatile memory device having a 2D structure may be arranged in a single layer on a substrate, and the memory cells of a nonvolatile memory device having a 3D structure may be vertically stacked on the substrate. Because the degree of integration of the nonvolatile memory device having a 3D structure is higher than that of the nonvolatile memory device having a 2D structure, the number of electronic devices using the nonvolatile memory device having a 3D structure has recently increased.

### SUMMARY

An embodiment of the present disclosure may provide for a method of manufacturing a memory device. The method may include forming a stacked body including first and second material layers on a lower structure, forming first openings passing through the stacked body, filling the first openings with preliminary contact plugs, respectively, forming, on the stacked body, a stepped structure including steps respectively corresponding to the preliminary contact plugs, forming second openings passing through respective steps of the stepped structure and open at least portions of the first openings, respectively, at different depths, exposing side surfaces of the second material layers by removing respective portions of the preliminary contact plugs adjacent to respective first sides of the first openings through the second openings, and forming the stacked body having a reverse step structure by removing exposed portions of the second material layers.

An embodiment of the present disclosure may provide for a memory device. The memory device may include a lower structure including pass transistors, a plurality contact plugs connected to the pass transistors, respectively, and configured to extend in a first direction, each of the plurality of contact plugs having different lengths from one another, and a plurality of conductive layers contacting the plurality of contact plugs, respectively, and stacked to be spaced apart from each other in the first direction, the plurality of conductive layers having a reverse step structure, wherein a first conductive layer among the plurality of conductive layers contacts a first contact plug among the plurality of contact plugs, and the first conductive layer penetrated by a gap-fill insulating layer disposed in the first direction, the gap-fill insulating layer extending from a second contact plug, among the plurality of contact plugs, in the first direction, and the second contact plug is shorter than the first contact plug in the first direction.

### BRIEF DESCRIPTION OF THE DRAWINGS

FIG. 1 is a diagram illustrating a memory device according to an embodiment of the present disclosure.

FIG. 2 is a diagram illustrating in detail global lines and local lines according to an embodiment of the present disclosure.

FIGS. 3A, 3B, 3C, and 3D are views illustrating a cell region and a contact region in a memory device according to an embodiment of the present disclosure.

FIGS. 4A, 4B, 4C, 4D, 4E, 4F, 4G, 4H, 4I, 4J, 4K, 4L, 4M, and 4N are views illustrating a method of manufacturing a memory device according to an embodiment of the present disclosure.

FIGS. 5A and 5B are diagrams illustrating conductive layers of a memory device according to an embodiment of the present disclosure.

FIG. 6 is a diagram illustrating a memory card system to which a memory device according to an embodiment of the present disclosure is applied.

FIG. 7 is a diagram illustrating a solid state drive (SSD) system to which a memory device according to an embodiment of the present disclosure is applied.

### DETAILED DESCRIPTION

Specific structural or functional descriptions in the embodiments according to the concept of the present disclosure introduced in this specification or application are only for description of the embodiments according to the concept of the present disclosure. The embodiments according to the concept of the present disclosure may be practiced in various forms, and should not be construed as being limited to the embodiments described in the specification or application.

Hereinafter, various embodiments of the present disclosure will be described in detail with reference to the accompanying drawings in which embodiments of the present disclosure are shown so that those skilled in the art to which the present disclosure pertains can practice the technical spirit of the present disclosure. In the description of the present disclosure, the terms “first” and “second” may be used to describe various components, but the components are not limited by the terms. The terms may be used to distinguish one component from another component. For example, a first component may be called a second component and a second component may be called a first component without departing from the scope of the present disclosure. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. Like numerals refer to like elements throughout. Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example of the term “below” can encompass both an orientation of above and below. The device may be otherwise oriented (rotated 90 degrees or at other orientations) and the spatially relative descriptors used herein interpreted accordingly.

Various embodiments of the present disclosure are directed to a memory device that is capable of improving electrical efficiency in a contact region of a memory device and a method of manufacturing the memory device.

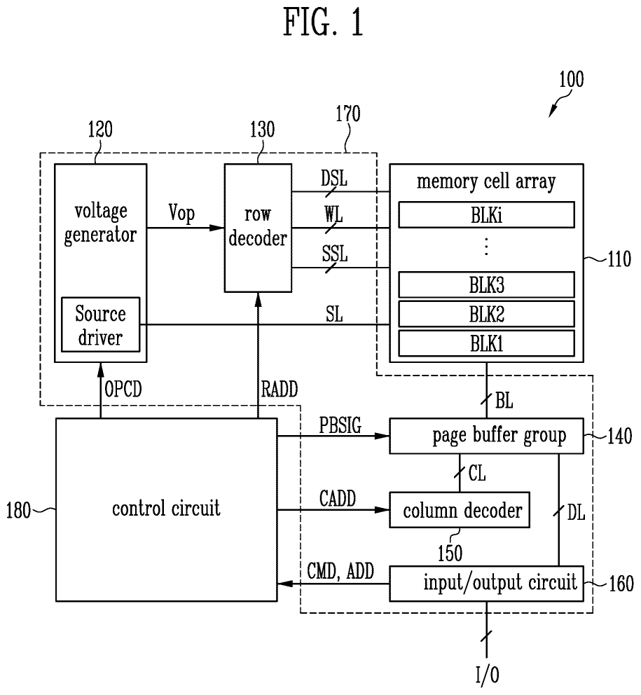

FIG. 1 is a diagram illustrating a memory device according to an embodiment of the present disclosure.

Referring to FIG. 1, a memory device 100 may include a memory cell array 110, a peripheral circuit 170, and a control circuit 180.

The memory cell array 110 may include first to i-th memory blocks BLK1 to BLKi. Each of the first to i-th memory blocks BLK1 to BLKi may include a plurality of memory cells that are capable of storing data. Drain select lines DSL, word lines WL, source select lines SSL, and a source line SL may be coupled to each of the first to i-th memory blocks BLK1 to BLKi, and bit lines BL may be coupled in common to the first to i-th memory blocks BLK1 to BLKi.

Each of the first to i-th memory blocks BLK1 to BLKi may be formed to have a three-dimensional (3D) structure. Each memory block having a 3D structure may include memory cells stacked on a substrate in a vertical direction.

According to a program scheme, each memory cell may store 1 bit of data or 2 or more bits of data. For example, a scheme for storing 1 bit of data in one memory cell is referred to as a single-level cell (SLC) scheme, and a scheme for storing 2 bits of data in one memory cell is referred to as a multi-level cell (MLC) scheme. A scheme for storing 3 bits of data in one memory cell is referred to as a triple-level cell (TLC) scheme, and a scheme for storing 4 bits of data in one memory cell is referred to as a quad-level cell (QLC) scheme. In addition, 5 or more bits of data may be stored in one memory cell.

The peripheral circuit 170 may perform a program operation of storing data in the memory cell array 110, a read operation of outputting data stored in the memory cell array 110, and an erase operation of erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop that are used for a program operation, a read operation, or an erase operation in response to an operation code OPCD. For example, the voltage generator 120 may generate program voltages, turn-on voltages, turn-off voltages, negative voltages, precharge voltages, verify voltages, read voltages, pass voltages, or erase voltages in response to the operation code OPCD. The operating voltages Vop generated by the voltage generator 120 may be applied to the drain select lines DSL, the word lines WL, and the source select lines SSL of a memory block selected through the row decoder 130.

The program voltages may be voltages that are applied to a selected word line among the word lines WL during a program operation, and may be used to increase the threshold voltages of memory cells coupled to the selected word line. The turn-on voltages may be applied to the drain select lines DSL or the source select lines SSL, and may be used to turn on drain select transistors or source select transistors. The turn-off voltages may be applied to the drain select lines DSL or the source select lines SSL, and may be used to turn off the drain select transistors or source select transistors. For example, the turn-off voltage may be set to 0 V. The precharge voltages may be voltages higher than 0 V, and may be applied to the bit lines during a read operation. The verify voltages may be used for a verify operation of determining whether the threshold voltages of selected memory cells have increased to a target level. The verify voltages may be set to various levels according to the target level, and may be applied to a selected word line.

The read voltages may be applied to the selected word line during a read operation performed on the selected memory cells. For example, the read voltages may be set to various levels according to the program scheme for the selected memory cells. The pass voltages may be voltages that are applied to unselected word lines among the word lines WL during a program or read operation, and may be used to turn on memory cells coupled to the unselected word lines. The erase voltages may be used during an erase operation of erasing the memory cells included in the selected memory block.

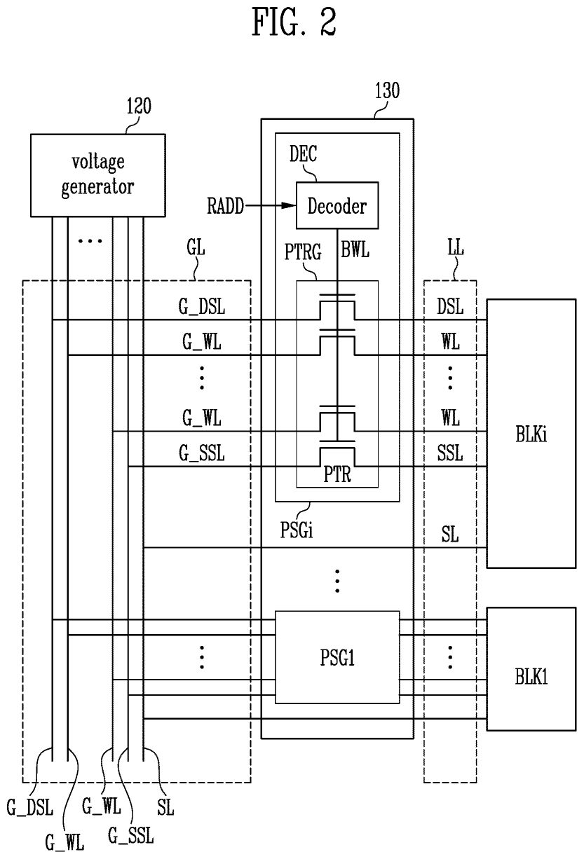

The row decoder 130 may transmit the operating voltages Vop to the drain select lines DSL, the word lines WL, and the source select lines SSL, which are coupled to a memory block selected according to a row address RADD. For example, the row decoder 130 may be coupled to the voltage generator 120 through global lines, and may be coupled to the first to i-th memory blocks BLK1 to BLKi through local lines (e.g., the drain select lines DSL, the word lines WL, and the source select lines SSL). The global lines and the local lines will be described in detail later with reference to FIG. 2.

The voltage generator 120 may include a source driver. The source driver may generate a source line voltage that is applied to the source line SL. The source line voltage may include a ground voltage or a positive voltage that is applied to the source line SL.

The page buffer group 140 may include page buffers (not illustrated) coupled to the first to i-th memory blocks BLK1 to BLKi, respectively. The page buffers (not illustrated) may be coupled to the first to i-th memory blocks BLK1 to BLKi through the bit lines BL. During a read operation the page buffers (not illustrated) may sense the currents or voltages of bit lines varying with the threshold voltages of the selected memory cells in response to page buffer control signals PBSIG, and may store the sensed data.

The column decoder 150 may be configured such that data is transferred between the page buffer group 140 and the input/output circuit 160 in response to a column address CADD. For example, the column decoder 150 may be coupled to the page buffer group 140 through column lines CL, and may transmit enable signals through the column lines CL. The page buffers (not illustrated) included in the page buffer group 140 may receive or output data through data lines DL in response to the enable signals.

The input/output circuit 160 may receive or output a command CMD, an address ADD, or data through input/output lines I/O. For example, the input/output circuit 160 may transmit the command CMD and the address ADD, received from an external controller through the input/output lines I/O, to the control circuit 180, and may transmit the data, received from the external controller through the input/output lines I/O, to the page buffer group 140. Alternatively, the input/output circuit 160 may output data, received from the page buffer group 140, to the external controller through the input/output lines I/O.

The control circuit 180 may output at least one of the operation code OPCD, the row address RADD, the page buffer control signals PBSIG, or the column address CADD in response to the command CMD and the address ADD. For example, when the command CMD input to the control circuit 180 is a command corresponding to a program operation, the control circuit 180 may control the peripheral circuit 170 so that a program operation is performed on a memory block selected by the address ADD. When the command CMD input to the control circuit 180 is a command corresponding to a read operation, the control circuit 180 may control the peripheral circuit 170 so that a read operation is performed on a memory block selected by the address and read data is output. When the command CMD input to the control circuit 180 is a command corresponding to an erase operation, the control circuit 180 may control the peripheral circuit 170 so that an erase operation is performed on a selected memory block.

FIG. 2 is a diagram illustrating in detail global lines and local lines according to an embodiment of the present disclosure.

Referring to FIG. 2, the row decoder 130 may include first to i-th pass switching groups PSG1 to PSGi respectively corresponding to first to i-th memory blocks BLK1 to BLKi. Although description will be made based on the configuration of the i-th pass switching group PSGi in FIG. 2 for convenience of description, the description of the i-th pass switching group PSGi may also be applied to the remaining pass switching groups.

The i-th pass switching group PSGi may include a decoder DEC, a block word line BWL, and a pass transistor group PTRG. The pass transistor group PTRG may include a plurality of pass transistors PTR.

The plurality of pass transistors PTR included in the pass transistor group PTRG may be coupled to the voltage generator 120 through global lines GL, and may be coupled to the i-th memory block BLKi through local lines LL. The local lines LL may include a drain select line DSL, word lines WL, and a source select line SSL. The global lines GL may include a global drain select line G_DSL, global word lines G_WL, and a global source select line G_SSL.

The row decoder 130 may couple the global lines GL to local lines LL coupled to a memory block, selected according to a row address RADD among the first to i-th memory blocks BLK1 to BLKi. Also, the row decoder 130 might not couple the global lines GL to local lines LL coupled to a memory block which is not selected according to the row address RADD among the first to i-th memory blocks BLK1 to BLKi.

The decoder DEC may turn on or off the pass transistors PTR by applying a block control signal to the block word line BWL according to the received row address RADD. In an example, when the decoder DEC receives a row address RADD for activating an i-th pass switching group PSGi, the decoder DEC may turn on the pass transistors PTR included in the i-th pass switching group PSGi by applying the block control signal having a high voltage to the block word line BWL. In an example, when the decoder DEC receives a row address RADD for deactivating the i-th pass switching group PSGi, the decoder DEC may turn off the pass transistors PTR included in the i-th pass switching group PSGi by deactivating the block control signal. For example, the deactivated block control signal may have a turn-off voltage.

When the pass transistors PTR of the i-th pass switching group PSGi are turned on, the global drain select line G_DSL and the drain select line DSL, the global word lines G_WL and the word lines WL, and the global source select line G_SSL and the source select line SSL may be electrically connected to each other through respective pass transistors PTR. When the pass transistors PTR are turned on, operating voltages (e.g., Vop of FIG. 1) generated by the voltage generator 120 may be transmitted to the i-th memory block BLKi through the global lines GL, the pass transistors PTR, and the local lines LL.

When the pass transistors PTR of the i-th pass switching group PSGi are turned off, the global drain select line G_DSL and the drain select line DSL, the global word lines G_WL and the word lines WL, and the global source select line G_SSL and the source select line SSL may be electrically disconnected from each other through respective pass transistors PTR. When the pass transistors PTR are turned off, the operating voltages Vop that are generated by the voltage generator 120 and applied to the global lines GL might not be transmitted to the i-th memory block BLKi.

The source line SL might not be coupled to the pass transistor PTR of the pass transistor group PTRG. For example, the source line SL may be directly connected to a source driver in the voltage generator 120. Therefore, the source line SL may be electrically connected to the source driver regardless of whether the pass transistors PTR of the i-th pass switching group PSGi are turned on or off.

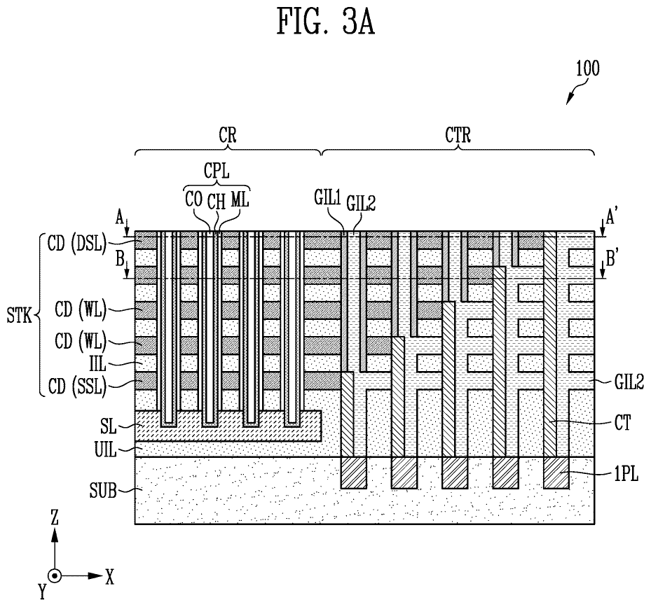

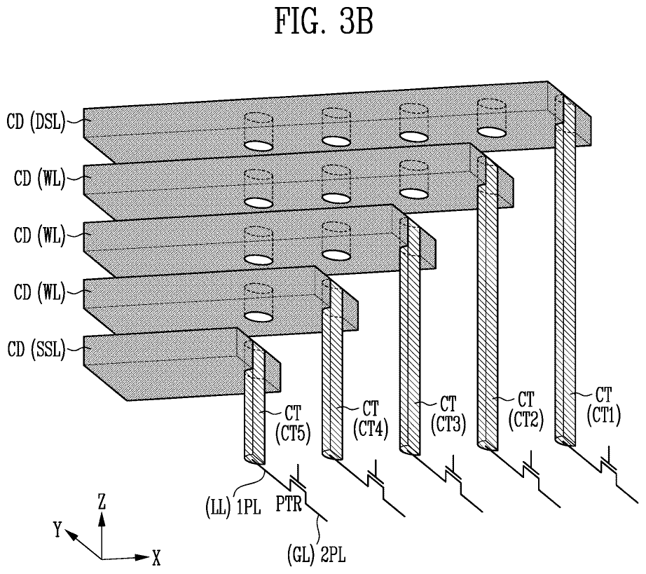

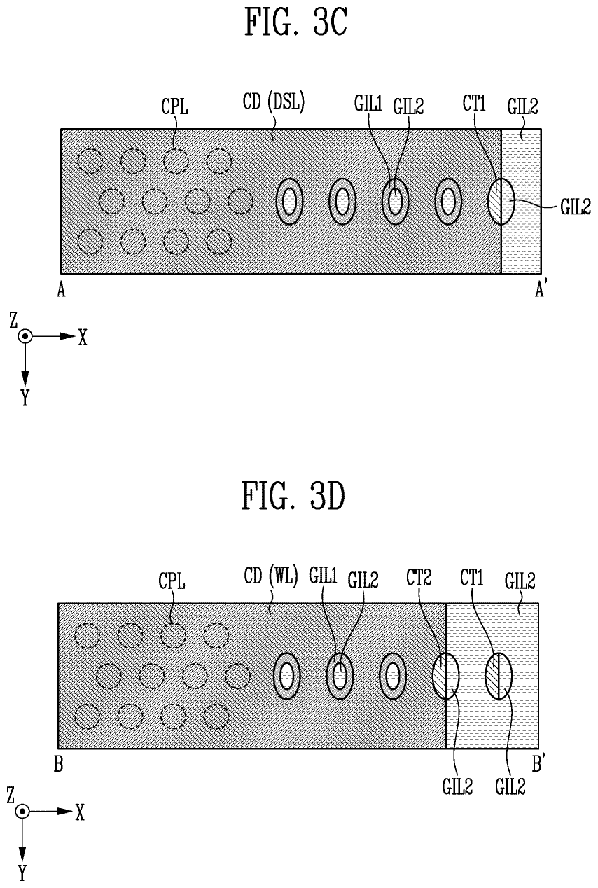

FIGS. 3A to 3D are views illustrating a cell region and a contact region of a memory device according to an embodiment of the present disclosure. FIG. 3A is a sectional view of the cell region and the contact region of the memory device. FIG. 3B is a view illustrating the structure of conductive layers and contact plugs of the memory device. FIG. 3C is a sectional view taken along line A-A′ of FIG. 3A. FIG. 3D is a sectional view taken along line B-B′ of FIG. 3A.

Referring to FIG. 3A, a memory device 100 may include a lower structure SUB. The lower structure SUB may include a substrate. The lower structure SUB may include at least a portion of the peripheral circuit of FIG. 1. For example, the pass transistors PTR of FIG. 2 and first pass lines 1PL coupled to the pass transistors PTR, respectively, may be disposed in the lower structure SUB. The first pass lines 1PL may be understood to be drains or sources of the respective pass transistors PTR of FIG. 2. For example, the first pass lines 1PL may be understood to be included in the local lines LL of FIG. 2. Referring to FIGS. 3A and 3B, the pass transistors PTR, the first pass lines 1PL, and second pass lines 2PL may be disposed in the lower structure SUB. The second pass lines 2PL may be understood to be sources or drains of the respective pass transistors PTR. For example, the first pass lines 1PL may be included in the local lines LL (indicated as (LL) 1PL in FIG. 3B), and the second pass lines 2PL may be included in the global lines GL (indicated as (GL) 2PL in FIG. 3B).

Referring to FIG. 3A, the memory device 100 may include a stacked body STK over the lower structure SUB. The stacked body STK may include conductive layers CD and interlayer insulating layers IIL that are alternately stacked along a Z direction (i.e., for some embodiments this may be the first direction). The conductive layers CD may be stacked to be spaced apart from each other in the Z direction. The conductive layers CD and the interlayer insulating layers IIL may individually extend along an X direction. The stacked body STK may correspond to any one of the memory blocks BLK1 to BLKi of FIGS. 1 and 2.

Each of the conductive layers CD may be formed of at least one of tungsten (W), cobalt (Co), nickel (Ni), molybdenum (Mo), silicon (Si), or polysilicon (Poly-Si). The conductive layers CD may be used as gate lines, for example, a drain select line DSL (indicated as CD (DSL) in FIG. 3A), word lines WL (indicated as CD (WL) in FIG. 3A), or a source select line SSL (indicated as CD (SSL) in FIG. 3A). Each of the interlayer insulating layers IIL may be formed of an oxide layer (e.g., silicon oxide layer).

The stacked body STK may include a cell region CR and a contact region CTR. The contact region CTR may extend from the cell region CR in the X direction. One or more cell plugs CPL may be formed in the cell region CR. One or more contact plugs CT may be formed in the contact region CTR. The locations, numbers, and arrangement states of the cell plugs CPL and the contact plugs CT, illustrated in FIG. 3A, correspond to one example, and are not intended to limit the scope of the present disclosure. In an example, the number of contact plugs CT may vary depending on the number of conductive layers CD. In an example, the contact plugs CT might not be arranged in a line along the X direction, but may be arranged to be misaligned with each other. In addition, the cell plugs CPL and the contact plugs CT may have various locations, numbers, and arrangement states.

The cell plugs CPL may extend in the Z direction within the cell region CR of the stacked body STK. The cell plugs CPL may penetrate the cell region CR of the stacked body STK in the Z direction. Each of the cell plugs CPL may include a cylindrical memory layer ML. The memory layer ML may include a blocking layer, a charge trap layer formed along an inner wall of the blocking layer, or a tunnel isolation layer formed along an inner wall of the charge trap layer, or a combination of at least two thereof. Each of the cell plugs CPL may include a channel layer CH formed along an inner wall of the memory layer ML and a core pillar CO formed in the channel layer CH.

Each of the blocking layer and the tunnel isolation layer included in the memory layer ML may be formed of an oxide layer (e.g., silicon oxide layer), an oxynitride layer (e.g., silicon oxynitride layer), or a combination thereof. The charge trap layer included in the memory layer ML may be a charge storage layer, and may include a nitride layer or a variable resistance material. The channel layer CH may be formed of a conductive layer (e.g., doped silicon layer). The channel layer CH may be replaced with an electrode structure. The core pillar CO may be formed of an insulating layer or a conductive layer. In an embodiment, a capping layer for improving electrical characteristics of select transistors may be further formed on the core pillar CO.

The cell plugs CPL may be coupled to the source line SL. The source line SL may be disposed between the cell region CR of the stacked body STK and the lower structure SUB. The source line SL may overlap the cell region CR. The source line SL may contact the channel layer CH included in each of the cell plugs CPL. Although not illustrated in the drawings, the source line SL may be electrically connected to the peripheral circuit 170 of the lower structure SUB.

Referring to FIGS. 3A and 3B, the contact region CR may have a stepped structure including a plurality of steps. Each of the plurality of steps may include one conductive layer CD and one interlayer insulating layer IIL. The contact region CTR may include a reverse step structure. The conductive layers CD may have a reverse step structure. In the present disclosure, the reverse step structure may refer to a stepped structure, the horizontal length of which decreases from the top (e.g., Z direction) to the bottom (e.g., direction opposite to the Z direction). Further, in the present disclosure, a forward step structure may refer to a stepped structure, the horizontal length of which increases from the top to the bottom. In FIGS. 3A and 3B, the lengths of the conductive layers CD in the X direction may increase in the Z direction. For example, the length of the drain select line DSL in the X direction may be greater than the length of the word lines WL in the X direction, and the length of the word lines WL in the X direction may be greater than the length of the source select line SSL in the X direction. In some embodiments, the X direction may be referred to as the second direction.

Referring to FIGS. 3A and 3B, the contact plugs CT may correspond to respective steps included in the stepped structure of the contact region CTR. Each of the contact plugs CT may be coupled to the conductive layer CD included in any one of the plurality of steps. The contact plugs CT may contact side surfaces of the conductive layers CD, respectively. For example, a first contact plug CT1 (indicated as CT (CT1) in FIG. 3B) may contact the conductive layer CD corresponding to the drain select line DSL (indicated as CD (DSL) in FIG. 3B). Further, a second contact plug CT2 (indicated as CT (CT2) in FIG. 3B), a third contact plug CT3 (indicated as CT (CT3) in FIG. 3B), and a fourth contact plug CT4 (indicated as CT (CT4) in FIG. 3B) may contact the conductive layers CD corresponding to the word lines WL (indicated as CD (WL) in FIG. 3B), respectively. Furthermore, a fifth contact plug CT5 (indicated as CT (CT5) in FIG. 3B) may contact the conductive layer CD corresponding to the source select line SSL (indicated as CD (SSL) in FIG. 3B).

Referring to FIGS. 3A and 3B, the contact plugs CT may couple the conductive layers CD to the pass transistors PTR, respectively. The contact plugs CT may electrically connect the conductive layers CD to the pass transistors PTR, respectively, by coupling the conductive layers CD to the first pass lines 1PL. For example, the first contact plug CT1 may couple the drain select line DSL to any one first pass lines 1PL. The second contact plug CT2 may couple the corresponding word line WL to any one first pass line 1PL. The fifth contact plug CT5 may couple the source select line SSL to any one first pass line 1PL. Each of the contact plugs CT may contain a conductive material (e.g., silicon). The contact plugs CT may penetrate a lower insulating layer UIL between the stacked body STK and the lower structure SUB.

The contact plugs CT may have different lengths in the Z direction. The heights of the contact plugs CT may be formed to be different from each other. For example, the first contact plug CT1 may be longer than the second contact plug CT2 in the Z direction. Also, the second contact plug CT2 may be longer than the third contact plug CT3 in the Z direction. Further, the third contact plug CT3 may be longer than the fourth contact plug CT4 in the Z direction. Furthermore, the fourth contact plug CT4 may be longer than the fifth contact plug CT5 in the Z direction.

The levels of the bottom surfaces of the contact plugs CT may be identical to each other. The bottom surfaces of the contact plugs CT may be located at the same level to contact the first pass lines 1PL. For example, the levels of the bottom surfaces of the contact plugs CT may be identical to the levels of the top surfaces of the first pass lines 1PL.

The levels of the top surfaces of the contact plugs CT may respectively correspond to the levels of the top surfaces of the conductive layers CD. The levels of the respective top surfaces of the contact plugs CT may be different from each other. For example, the top surface of the first contact plug CT1 may be located at the same level as the top surface of the conductive layer CD corresponding to the drain select line DSL. Further, the top surfaces of the second contact plug CT2, the third contact plug CT3, and the fourth contact plug CT4 may be located at the same levels as the top surfaces of the conductive layers CD respectively corresponding to the word lines WL. Furthermore, the top surface of the fifth contact plug CT5 may be located at the same level as the top surface of the conductive layer CD corresponding to the source select line SSL.

Referring to FIG. 3B, in an embodiment, the contact plugs CT may each have the shape of a semicircular column or a semielliptical column. In an embodiment, the planes of the contact plugs CT may each have a semicircular or semielliptical shape. In an embodiment, the cross-section of each of the contact plugs CT viewed in the Z direction may have a semicircular or semielliptical shape. For example, the left surfaces of the contact plugs CT may be curved surfaces, and the right surfaces thereof may be flat surfaces. A partial upper portion of the left surface of each of the contact plugs CT may contact the corresponding conductive layer CD. The right surface of each of the contact plugs CT and the right surface of the corresponding conductive layer CD may be located on the sample plane. In FIG. 3B, a right direction may indicate the X direction, and a left direction may indicate a direction opposite to the X direction.

Referring to FIG. 3A, gap-fill insulating layers GIL1 and GIL2 may be disposed on the contact plugs CT. First gap-fill insulating layers GIL1 may extend from the contact plugs CT in the Z direction. Each of the first gap-fill insulating layers GIL1 may, in an embodiment, have a cylindrical shape. The first gap-fill insulating layers GIL1 may contact the conductive layers CD and interlayer insulating layers IIL. Second gap-fill insulating layers GIL2 may fill the first gap-fill insulating layers GIL1. The second gap-fill insulating layers GIL2 may contact inner surfaces of the first gap-fill insulating layers GIL1. The first gap-fill insulating layers GIL1 and the second gap-fill insulating layers GIL2 may be formed of an identical or similar material. For example, each of the first and second gap-fill insulating layers GIL1 and GIL2 may include an oxide layer. Therefore, interfaces between the first gap-fill insulating layers GIL1 and the second gap-fill insulating layers GIL2 might not be observed.

The second gap-fill insulating layers GIL2 may extend to the side surfaces of the contact plugs CT. Each of the second gap-fill insulating layers GIL2 may protrude toward a level lower than that of the bottom surface of the corresponding first gap-fill insulating layer GIL1. The second gap-fill insulating layers GIL2 may contact the side surfaces of the contact plugs CT. The plane of the contact plugs CT and the second gap-fill insulating layers GIL2 viewed in the Z direction may, in an embodiment, have a circular or elliptical shape. Also, the second gap-fill insulating layers GIL2 may contact the lower insulating layer UIL. The second gap-fill insulating layers GIL2 and the lower insulating layer UIL may be formed of an identical or similar material, and thus the interface therebetween might not be observed.

The second gap-fill insulating layers GIL2 may extend to spaces between the interlayer insulating layers IIL. The second gap-fill insulating layers GIL2 may be located at the same level as the conductive layers CD. The second gap-fill insulating layers GIL2 may fill spaces between the interlayer insulating layers IIL of the stacked body STK. The second gap-fill insulating layers GIL2 may contact the top surfaces and the bottom surfaces of the interlayer insulating layers IIL. The second gap-fill insulating layers GIL2 and the interlayer insulating layers IIL may be formed of an identical or similar material, and thus the interface therebetween might not be observed.

Referring to FIGS. 3A and 3B, the gap-fill insulating layers GIL1 and GIL2 disposed on the contact plugs CT may penetrate the conductive layers CD. For example, the conductive layer CD corresponding to the drain select line DSL may be penetrated by the gap-fill insulating layers GIL1 and GIL2 disposed on the second contact plug CT2, the third contact plug CT3, the fourth contact plug CT4, and the fifth contact plug CT5. Furthermore, among the conductive layers CD corresponding to the word lines WL, the uppermost conductive layer CD may be penetrated by the gap-fill insulating layers GIL1 and GIL2 disposed on the third contact plug CT3, the fourth contact plug CT4, and the fifth contact plug CT5. Because illustration of the interlayer insulating layer IIL, the gap-fill insulating layers GIL1 and GIL2, and the lower insulating layer UIL is omitted in FIG. 3B, regions corresponding to the gap-fill insulating layers GIL1 and GIL2 penetrating the conductive layers CD may be shown as empty spaces.

Also, referring to FIGS. 3A and 3B, portions of the gap-fill insulating layers GIL1 and GIL2 disposed on the contact plugs CT may overlap the contact plugs CT. For example, an area occupied by the first and second gap-fill insulating layers GIL1 and GIL2 at a first level (e.g., level corresponding to the interlayer insulating layer IIL between DSL and WL) may be identical to an area occupied by the second contact plug CT2 and the second gap-fill insulating layer GIL2 at a second level (e.g., level corresponding to the interlayer insulating layer IIL between WL and WL). Further, the first and second gap-fill insulating layers GIL1 and GIL2 at the first level may overlap the second contact plug CT2 and the second gap-fill insulating layer GIL2 at the second level.

In relation to FIGS. 3C and 3D, configurations described with reference to FIGS. 3A and 3B may be omitted or described in brief. FIG. 3C illustrates the cross-section taken along line A-A′ of FIG. 3A, and FIG. 3D illustrates the cross-section taken along line B-B′ of FIG. 3A.

Referring to FIG. 3C, the conductive layer CD corresponding to the drain select line DSL (indicated as CD (DSL) in FIG. 3C) may contact the first contact plug CT1. The side surface of the conductive layer CD in the X direction may include a recess. The first contact plug CT1 may fill the recess of the conductive layer CD. The side surface of the conductive layer CD in the X direction may include a concave surface. The first contact plug CT1 may contact the concave surface of the conductive layer CD.

The side surface of the conductive layer CD in the X direction may contact the second gap-fill insulating layer GIL2. Because the second gap-fill insulating layer GIL2 fills spaces between the interlayer insulating layers IIL at the same level as the conductive layer CD, the second gap-fill insulating layer GIL2 may be disposed in the X direction of the conductive layer CD. Although, in FIG. 3C, the second gap-fill insulating layer GIL2 is illustrated as being divided into two regions, this illustration is provided for convenience of description, and the regions of the second gap-fill insulating layer GIL2 may be connected without an interface. That is, of the second gap-fill insulating layer GIL2, a region adjacent to the first contact plug CT1 and the remaining region may extend to each other without an interface.

The conductive layer CD may be penetrated by the gap-fill insulating layers GIL1 and GIL2 disposed on the second to fifth contact plugs CT2 to CT5. The first gap-fill insulating layer GIL1 may be disposed between the second gap-fill insulating layer GIL2 and the conductive layer CD. The interface between the first gap-fill insulating layer GIL1 and the second gap-fill insulating layer GIL2 might not be observed.

Referring to FIG. 3D, the conductive layer CD corresponding to the word line WL (indicated by CD (WL) in FIG. 3D) may contact the second contact plug CT2. The side surface of the conductive layer CD in the X direction may include a recess. The second contact plug CT2 may fill the recess of the conductive layer CD. The side surface of the conductive layer CD in the X direction may include a concave surface. The second contact plug CT2 may contact the concave surface of the conductive layer CD.

The side surface of the conductive layer CD in the X direction may contact the second gap-fill insulating layer GIL2. Because the second gap-fill insulating layer GIL2 fills spaces between the interlayer insulating layers IIL at the same level as the conductive layer CD, the second gap-fill insulating layer GIL2 may be disposed in the X direction of the conductive layer CD.

The first contact plug CT1 may be disposed in the X direction of the second contact plug CT2. The first contact plug CT1 might not contact the conductive layer CD corresponding to the word line WL. In the cross-section of B-B′, the first contact plug CT1 may be enclosed by the second gap-fill insulating layer GIL2.

Although, in FIG. 3D, the second gap-fill insulating layer GIL2 is illustrated as being divided into three regions, this illustration is provided for convenience of description, and the regions of the second gap-fill insulating layer GIL2 may be connected without an interface. That is, of the second gap-fill insulating layer GIL2, a region adjacent to the first contact plug CT1, a region adjacent to the second contact plug CT2, and the remaining region may extend to each other without an interface.

The conductive layer CD may be penetrated by the gap-fill insulating layers GIL1 and GIL2 disposed on the third to fifth contact plugs CT3 to CT5. The first gap-fill insulating layer GIL1 may be disposed between the second gap-fill insulating layer GIL2 and the conductive layer CD. The interface between the first gap-fill insulating layer GIL1 and the second gap-fill insulating layer GIL2 might not be observed.

According to various embodiments of the present disclosure, the stacked body STK has a reverse step structure, and thus an electrical path for connecting the conductive layers CD to the pass transistors PTR may be simplified. For example, because the conductive layers CD have a reverse step structure, each conductive layer CD may be connected to the first pass lines 1PL through one contact plug CT. Therefore, in an embodiment, the length of the electrical path connected from the peripheral circuit 170 to the conductive layers CD may be reduced compared to a conventional structure. That is, various embodiments of the present disclosure may improve electrical efficiency for controlling the memory device 100 by reducing the lengths of lines included in the contact region CTR.

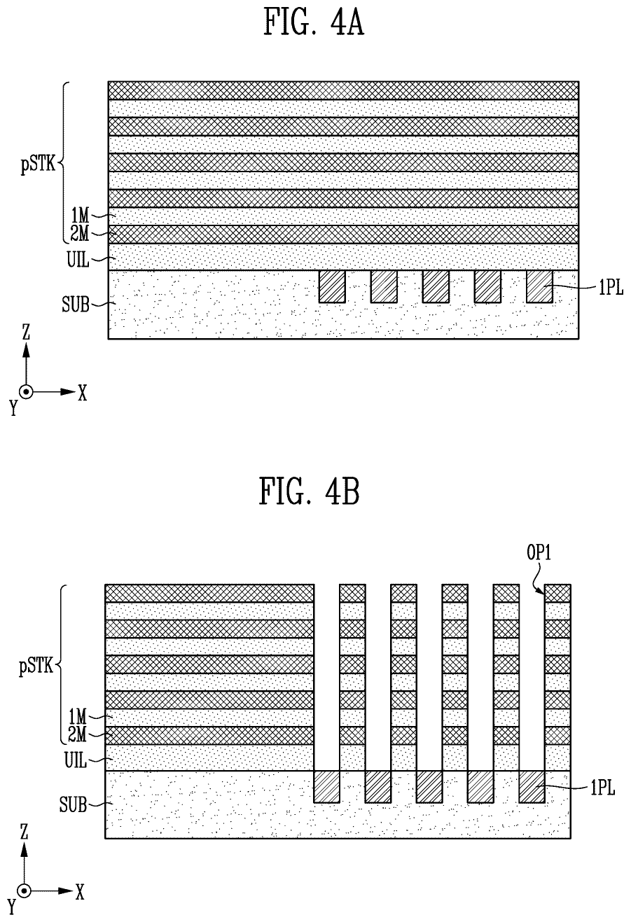

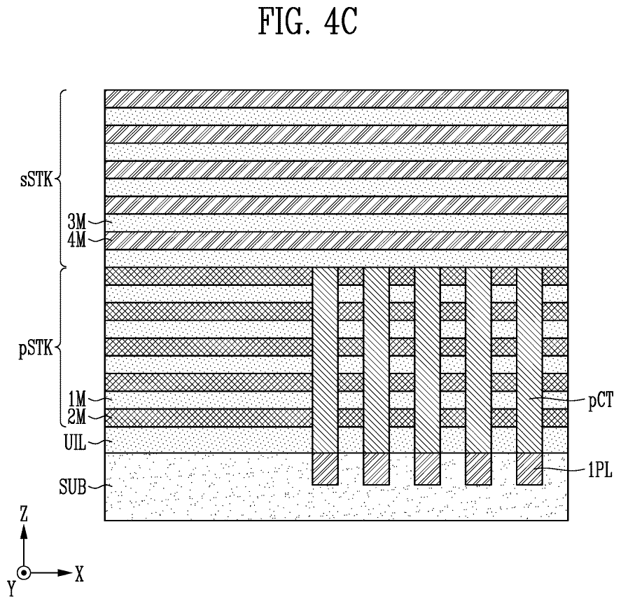

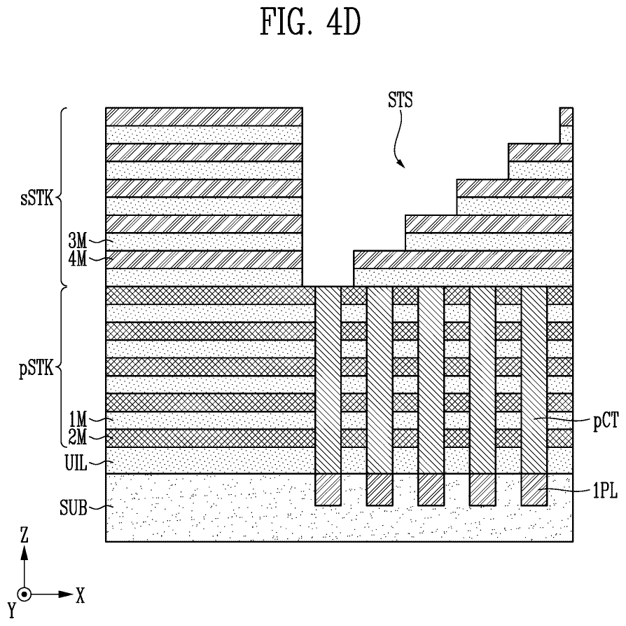

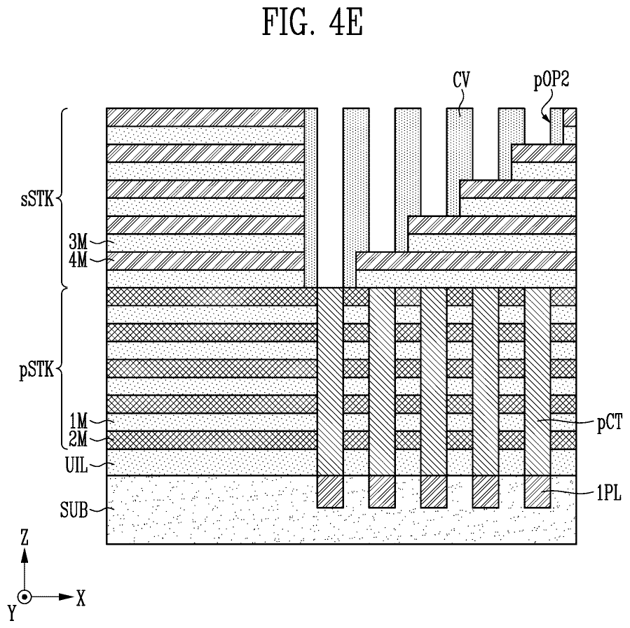

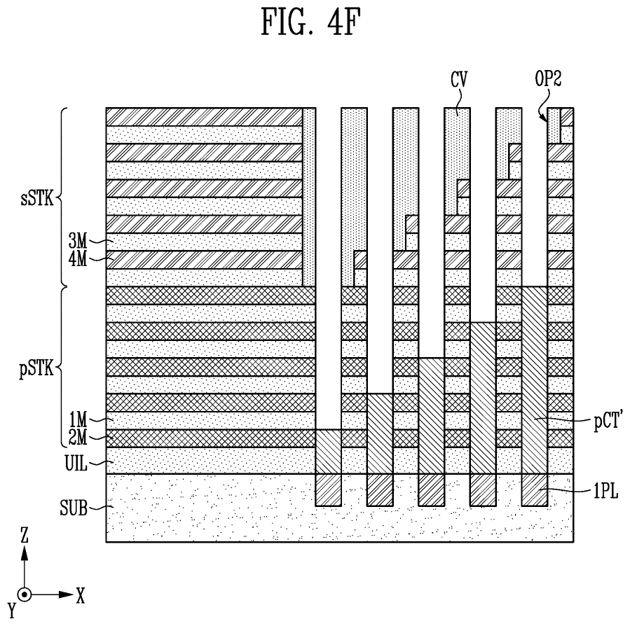

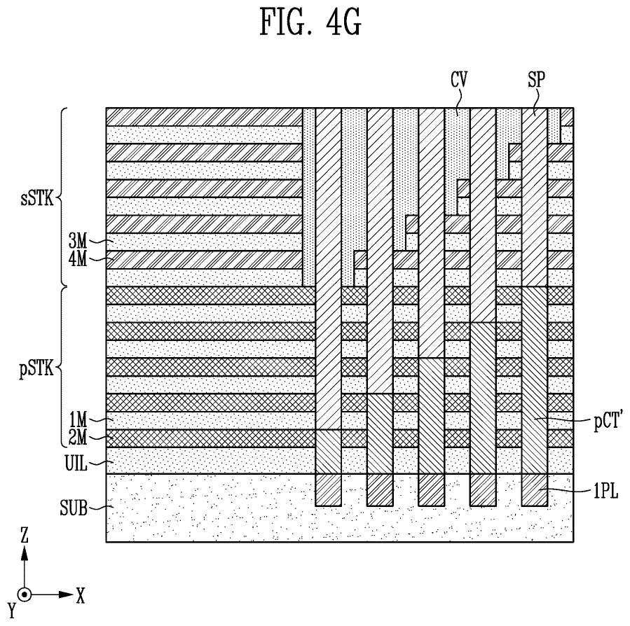

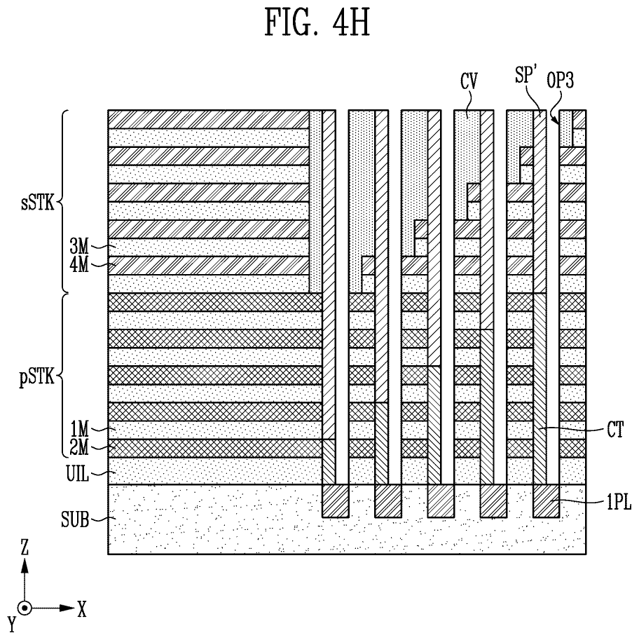

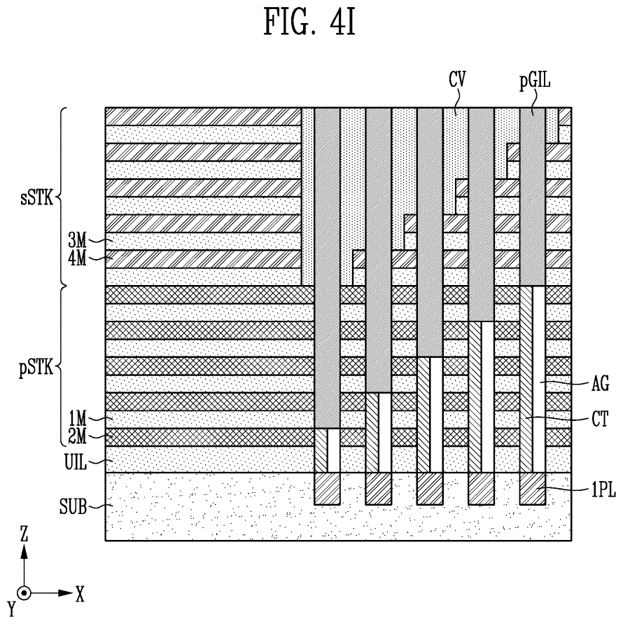

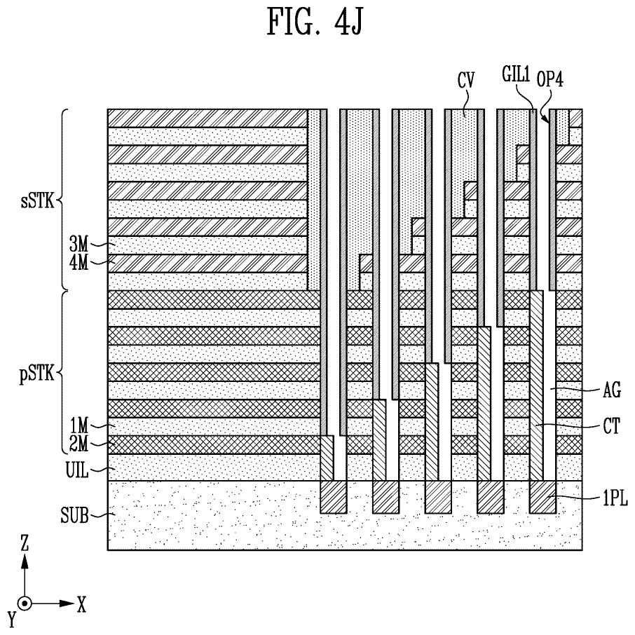

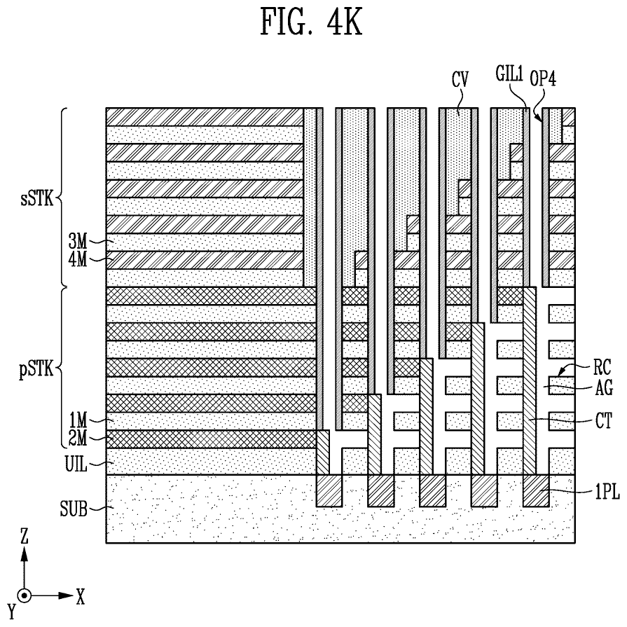

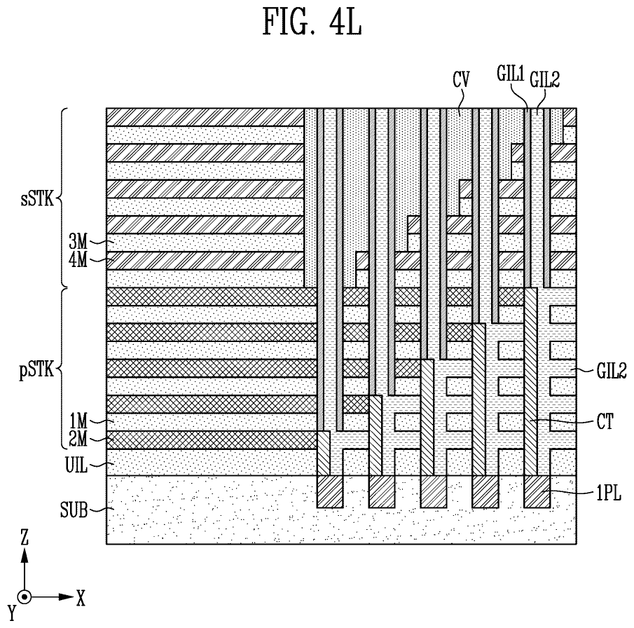

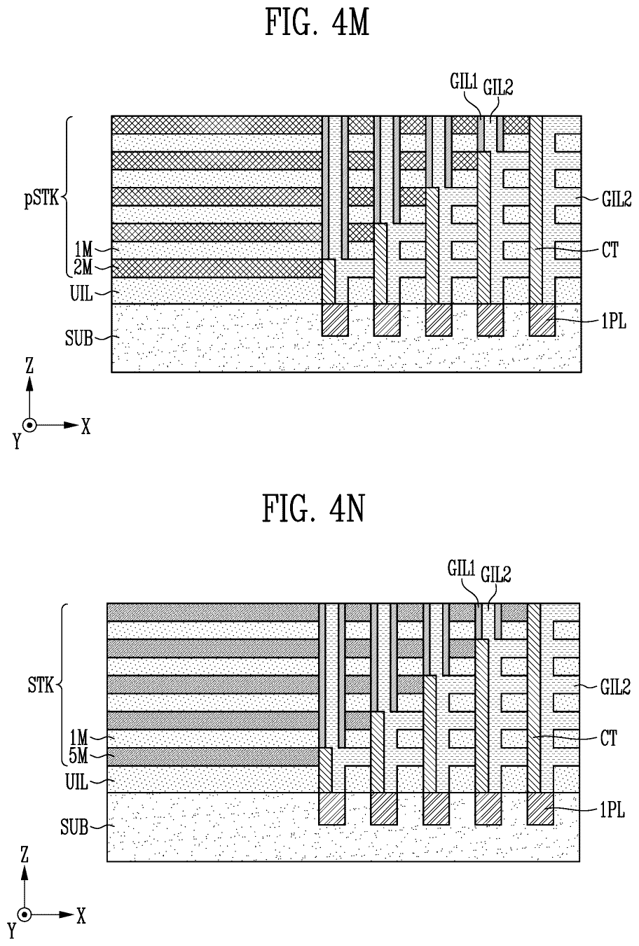

FIGS. 4A to 4N are views illustrating a method of manufacturing a memory device according to an embodiment of the present disclosure. In FIGS. 4A to 4N, a contact region CTR is mainly illustrated for convenience of description, and components included in a cell region CR may be omitted.

Referring to FIG. 4A, a lower structure SUB may be formed. The lower structure SUB may include first pass lines 1PL. The lower structure SUB may include the pass transistors PTR, the first pass lines 1PL, and the second pass lines 2PL of FIG. 3B. The first pass lines 1PL and the second pass lines 2PL may be coupled to respective pass transistors PTR.

Subsequently, a lower insulating layer UIL may be formed on the lower structure SUB. The lower insulating layer UIL may include an oxide layer. Although not illustrated in the drawings, the source line SL of FIG. 3A may be further formed in the lower insulating layer UIL.

Subsequently, a preliminary stacked body pSTK may be formed on the lower insulating layer UIL. The preliminary stacked body pSTK may include first material layers 1M and second material layers 2M. The first material layers 1M and the second material layers 2M may be alternately stacked along a Z direction. The first material layers 1M may correspond to the interlayer insulating layers IIL of FIG. 3A. Each of the first material layers 1M may be formed of an insulating material. For example, each of the first material layers 1M may be formed of an oxide layer (e.g., silicon oxide layer). Each of the second material layers 2M may be formed of a material that can be selectively removed in a subsequent process. The second material layers 2M may be formed of a material having an etch selectivity different from that of the first material layers 1M. For example, each of the second material layers 2M may be formed of a nitride layer.

Referring to FIG. 4B, first openings OP1 passing through the preliminary stacked body pSTK may be formed. The first openings OP1 may pass through the lower insulating layer UIL. The first openings OP1 may be formed in a contact region (e.g., the contact region CTR of FIG. 3A). The first openings OP1 may expose the first pass lines 1PL, respectively.

The plane of each of the first openings OP1 may have a circular or elliptical shape. Alternatively, the first openings OP1 may be formed to have various planar shapes in addition to the circular or elliptical shape.

Referring to FIG. 4C, the first openings OP1 may be filled with preliminary contact plugs pCT. The preliminary contact plugs pCT may fill the first openings OP1. The preliminary contact plugs pCT may contact the first pass lines 1PL, respectively. The level of the top surfaces of the preliminary contact plugs pCT may be identical to that of the top surface of the preliminary stacked body pSTK. The preliminary contact plugs pCT may contain a conductive material (e.g., polysilicon).

Subsequently, a sacrificial stacked body sSTK may be formed on the preliminary stacked body pSTK. The sacrificial stacked body sSTK may include third material layers 3M and fourth material layers 4M. The third material layers 3M and the fourth material layers 4M may be alternately stacked along the Z direction. Each of the third material layers 3M may be formed of an insulating material. For example, each of the third material layers 3M may be formed of an oxide layer (e.g., silicon oxide layer). The fourth material layers 4M may contain polysilicon. In an embodiment, the length of the third and fourth material layers 3M and 4M in the Z direction may correspond to the length of the first and second material layers 1M and 2M in the Z direction.

Referring to FIG. 4D, a portion of the sacrificial stacked body sSTK may be removed, and then a stepped structure STS may be formed. The sacrificial stacked body sSTK may include the stepped structure STS. The stepped structure STS may include a plurality of steps. The steps of the stepped structure STS may correspond to the preliminary contact plugs pCT, respectively. Each of the steps of the stepped structure STS may overlap any one of the preliminary contact plugs pCT. Each of the preliminary contact plugs pCT may overlap any one step.

The stepped structure STS may have a forward step structure. Therefore, the length of the stepped structure STS in the X direction may increase from the top (e.g., Z direction) to the bottom (e.g., direction opposite to the Z direction). For example, the number of third and fourth material layers 3M and 4M stacked on the preliminary contact plug pCT located on the rightmost side among the preliminary contact plugs pCT may be greater than the number of third and fourth material layers 3M and 4M stacked on the remaining preliminary contact plugs pCT.

Referring to FIG. 4E, a cover layer CV may be formed on the sacrificial stacked body sSTK. The cover layer CV may cover the stepped structure STS. The cover layer CV may cover the steps included in the stepped structure STS. The steps of the stepped structure STS may be covered by the cover layer CV.

Then, preliminary second openings pOP2 passing through the cover layer CV may be formed. The preliminary second openings pOP2 may pass through the cover layer CV to expose portions of the stepped structure STS. The preliminary second openings pOP2 may correspond to the steps of the stepped structure STS, respectively. The preliminary second openings pOP2 may overlap the first openings OP1. The preliminary second openings pOP2 may expose top surfaces of the respective steps included in the stepped structure STS. Some of the preliminary second openings pOP2 may expose the top surface of the corresponding preliminary contact plug pCT.

Because the levels (e.g., lengths in the Z direction) of the respective steps included in the stepped structure STS are different from each other, respective depths of the preliminary second openings pOP2 may be different from each other. For example, the depths of the preliminary second openings pOP2 may decrease in the X direction.

Referring to FIG. 4F, as respective depths of the preliminary second openings pOP2 increase, second openings OP2 may be formed. Respective bottom surfaces of the preliminary second openings pOP2 may be additionally etched, and then the second openings OP2 may be formed. For example, through the preliminary second openings pOP2, respective portions of the third and fourth material layers 3M and 4M of the stepped structure STS may be etched. Further, through the preliminary second openings pOP2, respective portions of the preliminary contact plugs pCT may be etched.

The second openings OP2 may pass through the respective steps of the stepped structure STS. At least some of the second openings OP2 may extend into the preliminary stacked body pSTK. The second openings OP2 may expose the side surface of the stepped structure STS and the side surface of the preliminary stacked body pSTK. The second openings OP2 may open at least portions of the first openings OP1, respectively, at different depths. For example, at least one second opening OP2 may open a portion of the corresponding first opening OP1. That is, at least one first opening OP1 may include an area opened by the corresponding second opening OP2.

The second openings OP2 may have different depths. The bottom surfaces of the second openings OP2 may be located at different levels. For example, the depths of the second openings OP2 may decrease in the X direction.

Preliminary contact plugs pCT′ may be disposed under the second openings OP2. The lengths of the preliminary contact plugs pCT′ in the Z direction may be different from each other. The preliminary contact plugs pCT′ may have different heights. The top surfaces of the preliminary contact plugs pCT′ may correspond to the top surfaces of the second material layers 2M, respectively. The top surfaces of the preliminary contact plugs pCT′ may be located at the same levels as the top surfaces of the second material layers 2M, respectively.

Referring to FIG. 4G, sacrificial pillars SP may be formed in the second openings OP2, respectively. The sacrificial pillars SP may fill the second openings OP2. The sacrificial pillars SP may contain a material having an etch selectivity with respect to the first to fourth material layers 1M to 4M and the preliminary contact plugs pCT′.

Referring to FIG. 4H, third openings OP3, each of which opens a portion of the corresponding first opening OP1 and a portion of the corresponding second opening OP2, may be formed. The third openings OP3 may open first sides of the respective first openings OP1 and first sides of the respective second openings OP2. Each of the third openings OP3 may have a semicircular or semi-elliptical plane. The third openings OP3 may expose the side surfaces of the respective first openings OP1 in the X direction and the side surfaces of the respective second openings OP2 in the X direction.

The third openings OP3 may be formed by removing respective portions of the sacrificial pillars SP and respective portions of the preliminary contact plugs pCT′. Respective portions of the sacrificial pillars SP′ adjacent to respective first sides of the second openings OP2 (e.g., semicircles or half ellipses in the X direction) may be removed. Further, respective portions of the preliminary contact plugs pCT′ adjacent to respective first sides of the first openings OP1 (e.g., semicircles or half ellipses in the X direction) may be removed. The respective portions of the preliminary contact plugs pCT′ may be removed, and thus contact plugs CT may remain. That is, portions, remaining after the preliminary contact plugs pCT′ are etched while the third openings OP3 are formed, may remain as the contact plugs CT.

The side surfaces of the sacrificial pillars SP may be exposed through respective left surfaces of the third openings OP3. Furthermore, the side surfaces of the contact plugs CT may be exposed through respective left surfaces of the third openings OP3. Furthermore, the side surfaces of the third and fourth material layers 3M and 4M of the stepped structure STS may be exposed through respective right surfaces of the third openings OP3. Furthermore, the side surfaces of the first and second material layers 1M and 2M of the preliminary stacked body pSTK may be exposed through respective right surfaces of the third openings OP3.

Referring to FIG. 4I, the sacrificial pillars SP′ may be removed. In order to selectively etch the sacrificial pillars SP′, an isotropic wet etching process may be performed.

Then, preliminary gap-fill insulating layers pGIL may be formed on the contact plugs CT. The preliminary gap-fill insulating layers pGIL may fill spaces from which the sacrificial pillars SP′ are removed. For example, the preliminary gap-fill insulating layers pGIL may fill the second openings OP2 of FIG. 4F. Therefore, the depths of the preliminary gap-fill insulating layers pGIL may be different from each other. For example, the lengths of the preliminary gap-fill insulating layers pGIL in the Z direction may decrease in the X direction.

The preliminary gap-fill insulating layers pGIL might not protrude toward the sides of the contact plugs CT. Therefore, air gaps AG may be formed in the X direction of the contact plugs CT. The air gaps AG may contact the side surfaces of the contact plugs CT in the X direction. The air gaps AG may be enclosed by the contact plugs CT, the preliminary gap-fill insulating layers pGIL, the first pass lines 1PL, and the preliminary stacked body pSTK.

The preliminary gap-fill insulating layers pGIL may contain a material having bad step coverage. Therefore, a preliminary gap-fill insulating layer gGIL might not be formed in an air gap AG having a relatively small width.

Referring to FIG. 4J, portions of the preliminary gap-fill insulating layers pGIL may be removed, and thus fourth openings OP4 may be formed. For example, respective central portions of the preliminary gap-fill insulating layers pGIL may be removed. The preliminary gap-fill insulating layers pGIL, which are partially removed, may remain as first gap-fill insulating layers GIL1. The first gap-fill insulating layers GIL1 may be disposed between the fourth openings OP4 and the sacrificial stacked body sSTK.

The fourth openings OP4 may have different depths. The depths of the fourth openings OP4 may correspond to the depths of the second openings OP2 described above with reference to FIG. 4F. That is, the fourth openings OP4 may have the same depths as the second openings OP2 of FIG. 4F, respectively. The bottom surfaces of the fourth openings OP4 may correspond to the top surfaces of the contact plugs CT. The bottom surfaces of the fourth openings OP4 may expose respective portions of the top surfaces of the contact plugs CT.

The air gaps AG may be exposed through the fourth openings OP4. For example, the plane of the third openings OP3 illustrated in FIG. 4H and the plane of the fourth openings OP4 of FIG. 4J may partially overlap each other. Therefore, the fourth openings OP4 may be coupled to the air gaps AG, respectively. In an embodiment, the fourth openings OP4 may be coupled to the air gaps AG, respectively, to form respective continuous openings between a single fourth opening overlapping with a signal air gap as shown in FIG. 4J.

The second material layers 2M of the preliminary stacked body pSTK may be exposed through the fourth openings OP4. Among the second material layers 2M, portions not covered by the first gap-fill insulating layers GIL1 or the contact plugs CT may be exposed to the outside.

Referring to FIG. 4K, the portions of the second material layers 2M, exposed through the fourth openings OP4 and the air gaps AG, may be removed. The exposed portions of the second material layers 2M may be removed, and then recesses RC may be formed. As respective portions of the second material layers 2M are removed, the remaining portions of the second material layers 2M may have a reverse step structure. For example, as the second material layers 2M are located in a lower portion, a larger area may be exposed to the outside through the fourth openings OP4 or the air gaps AG. Therefore, the lower the second material layers 2M are located, the more they may be removed.

Referring to FIG. 4L, second gap-fill insulating layers GIL2 may be formed in the fourth openings OP4, the air gaps AG, and the recesses RC. The second gap-fill insulating layers GIL2 may fill the fourth openings OP4, the air gaps AG, and the recesses RC. The second gap-fill insulating layers GIL2 may fill the air gaps AG and the recesses RC through the fourth openings OP4. The second gap-fill insulating layers GIL2 may contain a material having good step coverage. Therefore, regions (e.g., air gaps AG), which are not filled with the preliminary gap-fill insulating layers pGIL in FIG. 4I, may be filled with the second gap-fill insulating layers GIL2.

Referring to FIG. 4M, the sacrificial stacked body sSTK on the preliminary stacked body pSTK may be removed. The third and fourth material layers 3M and 4M stacked on the preliminary stacked body pSTK may be removed. Further, the stepped structure STS and the cover layer CV may be removed. Furthermore, portions of the first and second gap-fill insulating layers GIL1 and GIL2 may be removed.

Referring to FIG. 4N, the second material layers 2M may be replaced with fifth material layers 5M. The portions of the second material layers 2M, remaining without being removed in FIG. 4K, may be replaced with fifth material layers 5M. The fifth material layers 5M may correspond to the conductive layers CD of FIGS. 3A to 3D. The first material layers 1M and the fifth material layers 5M that are alternately stacked may form a stacked body STK. The stacked body STK may include fifth material layers 5M having a reverse step structure.

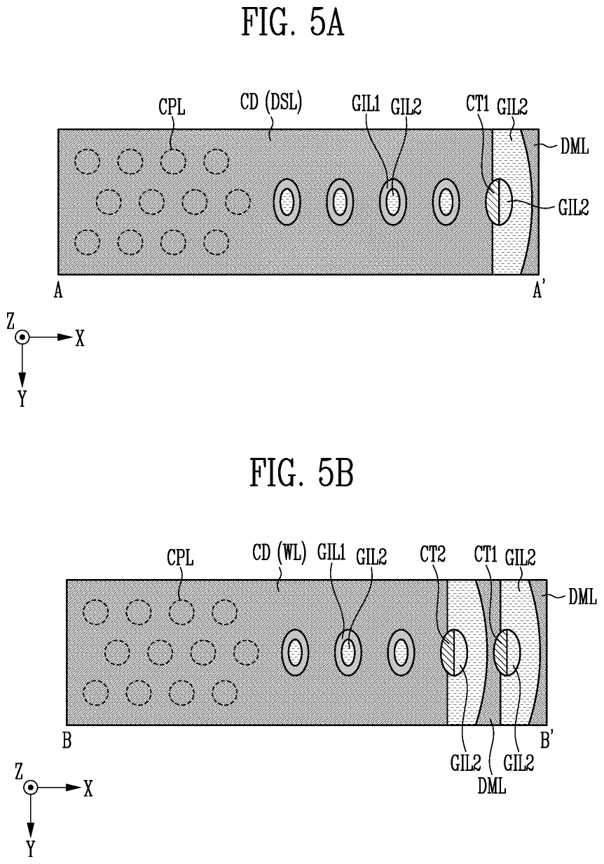

FIGS. 5A and 5B are diagrams illustrating conductive layers of a memory device according to an embodiment of the present disclosure. FIG. 5A is a sectional view taken along line A-A′ of FIG. 3A. FIG. 5B is a sectional view taken along line B-B′ of FIG. 3A. In relation to FIGS. 5A and 5B, configurations, described above with reference to FIGS. 3A to 3D and FIGS. 4A to 4N, may be described in brief, or description thereof may be omitted.

As described above with reference to FIG. 4K, the cross-sections of FIGS. 3C and 3D may be changed to those of FIGS. 5A and 5B, depending on the direction or speed at which second material layers 2M are etched while the exposed portions of the second material layers 2M are removed.

Referring to FIG. 5A, the side surface of a first contact plug CT1 in an X direction may protrude, in the X direction, beyond the side surface of a conductive layer CD corresponding to a drain select line DSL in the X direction. Further, a dummy layer DML may be disposed in the X direction of the conductive layer CD. The dummy layer DML may be located at the same level as the conductive layer CD. The dummy layer DML may contain the same material as the conductive layer CD. The dummy layer DML may contact a second gap-fill insulating layer GIL2. The interface between the second gap-fill insulating layer GIL2 and the dummy layer DML may form a curved surface. For example, when a region from which the second material layers 2M are removed in FIG. 4K leans to the left (e.g., in a direction opposite to the X direction) compared to FIG. 3C, the conductive layer CD and the dummy layer DML, each having a plane such as that illustrated in FIG. 5A, may be formed.

Referring to FIG. 5B, the side surface of a second contact plug CT2 in an X direction may protrude, in the X direction, beyond the side surface of the conductive layer CD corresponding to a word line WL in the X direction. Further, dummy layers DML may be disposed in the X direction of the conductive layer CD. The first contact plug CT1 may contact any one dummy layer DML. However, in an embodiment, because the dummy layer DML is floating, the dummy layer DML might not influence the operation of the memory device 100 even if the dummy layer DML contacts the first contact plug CT1.

The cross-sections illustrated in FIGS. 5A and 5B, may correspond to one example, and the conductive layer CD, the dummy layer DML, and the second gap-fill insulating layer GIL2 may have various planar shapes in addition to the example.

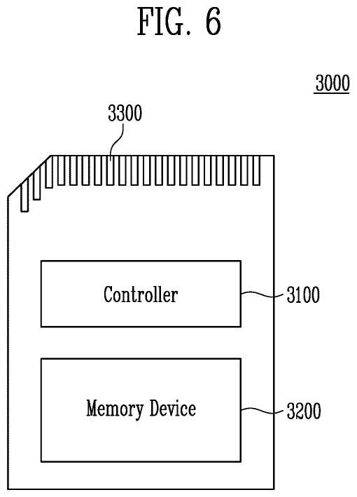

FIG. 6 is a diagram illustrating a memory card system to which a memory device according to an embodiment of the present disclosure is applied.

Referring to FIG. 6, a memory card system 3000 may include a controller 3100, a memory device 3200, and a connector 3300.

The controller 3100 may be coupled to the memory device 3200. The controller 3100 may access the memory device 3200. For example, the controller 3100 may control a program operation, a read operation, or an erase operation of the memory device 3200, or may control a background operation of the memory device 3200. The controller 3100 may provide an interface between the memory device 3200 and a host. The controller 3100 may run firmware for controlling the memory device 3200. In an example, the controller 3100 may include components, such as a random access memory (RAM), a processor, a host interface, a memory interface, and an error corrector.

The controller 3100 may communicate with an external device through the connector 3300. The controller 3100 may communicate with an external device (e.g., a host) based on a specific communication standard. For example, the controller 3100 may communicate with the external device through at least one of various communication standards such as universal serial bus (USB), multimedia card (MMC), embedded MMC (eMMC), peripheral component interconnection (PCI), PCI-express (PCI-E), advanced technology attachment (ATA) protocol, serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe). For example, the connector 3300 may be defined by at least one of the above-described various communication standards.

The memory device 3200 may include a plurality of memory cells, and may be configured in the same manner as the memory device 100 illustrated in FIG. 1.

The controller 3100 and the memory device 3200 may be integrated into a single semiconductor device to form a memory card. For example, the controller 3100 and the memory device 3200 may be integrated into a single semiconductor device, and may then form a memory card such as a personal computer memory card international association (PCMCIA) card, a compact flash card (CF), a smart media card (SM or SMC), a memory stick, a multimedia card (MMC, RS-MMC, MMCmicro or eMMC), an SD card (SD, miniSD, microSD, or SDHC), or a universal flash storage (UFS).

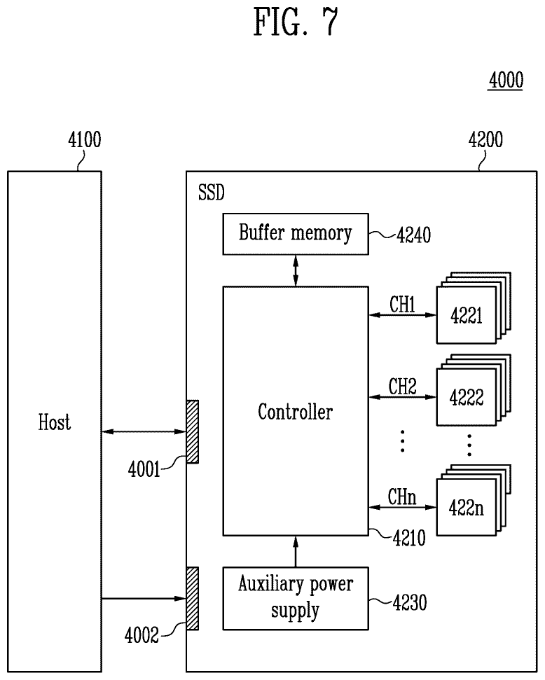

FIG. 7 is a diagram illustrating a solid state drive (SSD) system to which a memory device according to the present disclosure is applied.

Referring to FIG. 7, an SSD system 4000 may include a host 4100 and an SSD 4200. The SSD 4200 may exchange signals with the host 4100 through a signal connector 4001, and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to signals received from the host 4100. For example, the received signals may be signals based on the interfaces of the host 4100 and the SSD 4200. For example, the signals may be defined by at least one of various interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe).

Each of the plurality of memory devices 4221 to 422n may include a plurality of memory cells configured to store data. Each of the memory devices 4221 to 422n may be configured in the same manner as the memory device 100 illustrated in FIG. 1. The plurality of memory devices 4221 to 422n may communicate with the controller 4210 through channels CH1 to CHn.

The auxiliary power supply 4230 may be coupled to the host 4100 through the power connector 4002. The auxiliary power supply 4230 may be supplied with a supply voltage from the host 4100, and may be charged. The auxiliary power supply 4230 may provide the supply voltage of the SSD 4200 when the supply of power from the host 4100 is not smoothly performed. For example, the auxiliary power supply 4230 may be located inside the SSD 4200 or located outside the SSD 4200. For example, the auxiliary power supply 4230 may be located in a main board, and may provide auxiliary power to the SSD 4200.

The buffer memory 4240 may function as a buffer memory of the SSD 4200. For example, the buffer memory 4240 may store, for a limited duration of time, data received from the host 4100 or data received from the plurality of memory devices 4221 to 422n, or may store, for a limited duration of time, metadata (e.g., mapping tables) of the memory devices 4221 to 422n. The buffer memory 4240 may include volatile memories, such as a dynamic random access memory (DRAM), a synchronous DRAM (SDRAM), a double data rate (DDR) SDRAM, and a low power DDR (LPDDR) SDRAM, or nonvolatile memories, such as a ferroelectric RAM (FRAM), a resistive RAM (ReRAM), a spin transfer torque magnetic RAM (STT-MRAM), and a phase-change RAM (PRAM).

Various embodiments of the present disclosure may improve electrical efficiency for controlling a memory device by reducing the length of lines in a contact region.

What is claimed is:

1. A method of manufacturing a memory device, comprising:
forming a stacked body including first and second material layers on a lower structure;
forming first openings passing through the stacked body;
filling the first openings with preliminary contact plugs, respectively;
forming, on the stacked body, a stepped structure including steps respectively corresponding to the preliminary contact plugs;
forming second openings passing through respective steps of the stepped structure and open at least portions of the first openings, respectively, at different depths;
exposing side surfaces of the second material layers by removing respective portions of the preliminary contact plugs adjacent to respective first sides of the first openings through the second openings; and
forming the stacked body having a reverse step structure by removing exposed portions of the second material layers.

2. The method according to claim 1, further comprising, before forming the stacked body:
forming the lower structure including pass transistors and pass lines connected to the pass transistors, respectively.

3. The method according to claim 2, wherein forming the first openings comprises:
forming the first openings to expose the pass lines, respectively.

4. The method according to claim 1, wherein forming the stepped structure comprises:
forming a sacrificial stacked body including third and fourth material layers on the stacked body; and
forming the stepped structure having a forward step structure by removing a portion of the sacrificial stacked body.

5. The method according to claim 1, wherein forming the second openings comprises:
forming a cover layer that covers the stepped structure;
forming preliminary second openings that pass through the cover layer to expose top surfaces of the respective steps; and
etching the stepped structure and the preliminary contact plugs through the preliminary second openings.

6. The method according to claim 1, wherein, after forming the second openings, the preliminary contact plugs have different heights.

7. The method according to claim 1, wherein, after forming the second openings, respective top surfaces of the preliminary contact plugs are located at levels substantially even with respective top surfaces of the second material layers.

8. The method according to claim 1, wherein exposing the side surfaces of the second material layers through the second openings comprises:
filling the second openings with respective sacrificial pillars;
forming third openings that open the respective first sides of the first openings and respective first sides of the second openings; and
exposing the side surfaces of the second material layers through the third openings.

9. The method according to claim 8, wherein forming the third openings comprises:
removing respective portions of the sacrificial pillars adjacent to the respective first sides of the second openings; and
removing the respective portions of the preliminary contact plugs adjacent to the respective first sides of the first openings.

10. The method according to claim 8, wherein forming the third openings comprises:
forming contact plugs by removing the respective portions of the preliminary contact plugs.

11. The method according to claim 10, further comprising, after exposing the side surfaces of the second material layers through the third openings:
removing the sacrificial pillars;
forming preliminary gap-fill insulating layers that fill the second openings on the contact plugs; and
forming fourth openings by removing respective portions of the preliminary gap-fill insulating layers.

12. The method according to claim 11, wherein forming the preliminary gap-fill insulating layers comprises:
forming air gaps that contact side surfaces of the contact plugs.

13. The method according to claim 12, wherein forming the fourth openings comprises:
exposing the air gaps through the fourth openings.

14. The method according to claim 11, wherein forming the stacked body having the reverse step structure by removing the exposed portions of the second material layers comprises:
removing the second material layers through the fourth openings.

15. The method according to claim 1, further comprising, after forming the stacked body having the reverse step structure by removing the exposed portions of the second material layers:
filling regions from which the exposed portions of the second material layers are removed with a gap-fill insulating layer; and
replacing remaining portions of the second material layers with fifth material layers.

16. A memory device, comprising:
a lower structure including pass transistors;
a plurality contact plugs connected to the pass transistors, respectively, and configured to extend in a first direction, each of the plurality of contact plugs having different lengths from one another; and
a plurality of conductive layers contacting the plurality of contact plugs, respectively, and stacked to be spaced apart from each other in the first direction, the plurality of conductive layers having a reverse step structure,
wherein a first conductive layer among the plurality of conductive layers contacts a first contact plug among the plurality of contact plugs, and the first conductive layer penetrated by a gap-fill insulating layer disposed in the first direction, the gap-fill insulating layer extending from a second contact plug, among the plurality of contact plugs, in the first direction, and the second contact plug is shorter than the first contact plug in the first direction.

17. The memory device according to claim 16, wherein a top surface of the first contact plug is located at substantially the same level as a top surface of the first conductive layer.

18. The memory device according to claim 16, wherein a side surface of the first contact plug contacts a side surface of the first conductive layer.

19. The memory device according to claim 16, wherein a second conductive layer among the conductive layers contacts the second contact plug, and is located in a direction opposite to the first direction with respect to the first conductive layer.

20. The memory device according to claim 19, wherein:
a length of the second conductive layer in a second direction is smaller than a length of the first conductive layer in the second direction, and
the second direction intersects the first direction.

21. The memory device according to claim 16, wherein a portion of the gap-fill insulating layer overlaps the second contact plug.
